(19) United States
(12) Patent Application Publication
(10) Pub. No.: US 2004/0072108 A1
(43) Pub. Date: Apr. 15, 2004

(54) Method of forming resist patterns in a semiconductor device and a semiconductor washing liquid used in said method

(76) Inventor: Man-Sok Hyon, Gyehggi-do (KR)

Correspondence Address: Jonathan Y Kang, Lee Hong Degerman Kang & Schmadeka, 14th Floor, 801 South Fiqueroa Street, Los Angeles, CA, 90017, US

(21) Appl. No.: 10/469,175

(22) PCT Filed: Feb. 7, 2002
(86) PCT No.: PCT/KR02/00188

(30) Foreign Application Priority Data
Feb. 22, 2001 (KR) 2001/8876

(51) Int. Cl. G03F 7/00; G03F 7/32

(52) U.S. Cl. 430/331; 430/322; 430/329

(57) ABSTRACT

This invention relates to a resist patterning method of preventing resist pattern collapse, which is occurred as the minimum pattern size becomes smaller, in photolithography for making semiconductor device and also introduce novel rinse liquid in which fluorocarbon surfactant having hydrophobic group and hydrophilic group is dissolved in deionezed water and have low surface tension for preventing resist pattern collapse in wet development method. With this invention, the fine resist pattern can be obtained without resist pattern collapse from conventional wet development method with no additional specific instrument for prevention of resist pattern collapse.

### TECHNICAL FIELD

The present invention relates to a method of forming a resist pattern of a semiconductor device and semiconductor wafer cleaning liquid used in the method. More particularly, the present invention relates to a method of forming a resist pattern wherein a resist pattern collapse, which occurs in photolithography for forming the resist pattern onto the a wafer as a minimum resist pattern size (DICD; after Development Inspection Critical Dimension) becomes smaller, can be prevented.

### BACKGROUND ART

Lithography is a process by which a resist pattern is formed on a wafer by passing light through a mask with a semiconductor circuit patterned thereon so that the pattern can be transferred from the mask to a photoresist. All the layout of the semiconductor device and wiring for use in a semiconductor integrated circuit is formed onto the wafer through the lithographic process.

Resist pattern collapse occurs in a development process among the lithographic process, and it is mainly categorized into two types. First, the resist pattern is peeled off from a wafer substrate due to low adhesion therebetween. Second, the resist pattern is curved or broken because of its low rigidity.

Resist pattern collapse in the wet development method occurs in the following process step. Development process is carried out by the treatment of developing solution and followed by the rinsing with the deionized water and spin drying with high speed rotation of the wafer. In these described steps, the collapse force is driven during spin drying process after the rinse step is finished. The resist pattern is collapsed when it cannot overcome this collapse force.

Resist pattern collapse is occurred more easily as the integration of the semiconductor device is higher. The factors of the resist pattern collapse are the surface tension of the rinse liquid, aspect ratio which is the ratio of pattern height with the pattern width, pattern space and the contact angle between resist pattern and rinse liquid. The relation with these factors is described the following formula. And FIG. 1 shows schematic diagram for describing collapse force causing resist pattern collapse

$$Collapse force = \frac{6 γ cos θ}{D} {( \frac{H}{W} )}^{2}$$

where, γ is the surface tension of the rinse liquid, θ is the contact angle between the resist pattern and the rinse liquid, D is the pattern space between the resist patterns, H is the pattern height and W is the pattern width. According to the above equation, the collapse force which is the capillary attraction between the resist patterns is proportional to the surface tension of the rinse liquid, aspect ratio and cosine value of the contact angle between resist pattern and the rinse liquid. And it is an inverse proportional to the pattern space. In the above sentence, the small pattern space means the narrow space between the resist patterns, and small pattern width means that the critical dimension of the resist pattern is small. Therefore, the collapse force becomes more strong as the integration of the semiconductor device gets higher. So pattern collapse is more easily occurred as the integration of the device gets higher.

Many research has been done to overcome this resist pattern collapse issue in the worldwide. At first, Korean Patent No. 172549 (Korean Patent Application No. 1996-23211) discloses a process for preventing resist pattern collapse by hardening of the resist pattern with the treatment of hot deionized water after washing with the normal temperature deionized water, and then drying with the spin dry method. This patent is effective to prevent resist pattern collapse which is broken type or bending type. But fine pattern of sub-100 nm is too thin to collapse although it is sufficiently strong. So this method has a limit to solve the pattern collapse

Next, Korean Patent Application No. 10-1998-0050982 (Korean Patent Laid-open Publication No. 2000-0033916) discloses a process technique in which the contact angle between the rinse liquid and resist pattern is made vertical by using vibrator such as ultrasonic generator or electromagnetic wave generator. This method aim to control resist pattern collapse by reducing collapse force by making the contact angle 90 degree.

This method assumed that all the surface of the rinse liquid is flat when the wafer is rotated in a high speed of 4000 rpm. But all the surface of the rinse liquid cannot be made flat in during such a shot time. Resist pattern collapse can be occurred in some local area in which the surface of the rinse liquid is not flat. It also need to make a new development machine which have a ultrasonic vibrator or elecromagnetic wave generator. Making such a sophisticated machine is very difficult.

And following two inventions describe the method for preventing resist pattern collapse by lowering surface tension of the rinse liquid.

The Paper, Jpn. J. Appl. Phys. Vol. 32 (1993) pp. 6059, by Toshihiko Tanaka described the method of using new rinse liquid in which tert-butyl alcohol is added to deionized water to lower the surface tension of rinse liquid. But in this method more than 20% of tert-butyl alcohol is used to make sufficiently low surface tension of the rinse liquid. It cannot be used for the application of semiconductor device because this rinse liquid dissolves the resist pattern so that it changes the critical dimension of the pattern.

The paper, Microelectronic engineering 46 (1999) pp. 129, by Hideo Namatsu described new process using carbon dioxide with the fact that the surface tension of supercritical fluid is nearly zero. Liquid carbon dioxide is ejected on the wafer at the temperature of below 10° C., and then the temperature is elevated to above 35° C. and pressure is optimized at high pressure of around 7.5 Mpa. In this hard condition the carbon dioxide becomes supercritical fluid, which is the condition of gas having high density or liquid state being capable of diffusion. There is no boundary between gas state and liquid state in supercritical condition.

But this method use liquid carbon dioxide of highly expensive and should develop new machine which can control the temperature from 10° C. to 35° C. and make high pressure of 7.5 Mpa. Moreover, this method should eject carbon dioxide of supercritical fluid at low speed of 1 liter per minute. It takes much time to process one wafer so that it produces low throughput. It is strong demerit for the mass production of semiconductor device and questionable for the real application.

### DISCLOSURE OF INVENTION

This invention aims to provide new resist patterning technology which is preventing resist pattern collapse at the micro patterns.

And, this invention aims to provide resist patterning technology without additional new machine for the prevention of resist pattern collapse, which use conventional development machine.

And this invention aims to provide additives whose solution in water have low surface tension and does not dissolve resist pattern.

And this invention aims to provide new rinse liquid which can prevent resist pattern collapse.

### GRIEF DESCRIPTION OF DRAWINGS

FIG. 1 is a schematic view showing width and height of a resist pattern for explaining force used for causing the resist pattern to collapse.

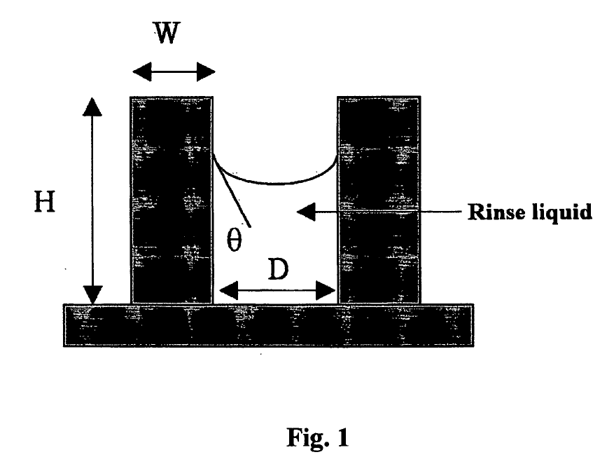

FIG. 2 is a sectional view illustrating a conventional process for forming a fine resist pattern.

FIG. 3 is a graph showing relationship between a surface tension and a concentration of fluorocarbon surfactant having hydrophilic group and hydrophobic group according to the present invention.

FIG. 4 is a sectional view illustrating a principle that a surface tension of water solution with fluorocarbon surfactant having hydrophilic group and hydrophobic group added therein is lowered according to the present invention.

FIG. 5 is a sectional view illustrating a process for forming a resist pattern according to a first embodiment of the present invention.

FIG. 6 is a sectional view illustrating a process for forming a resist pattern according to a second embodiment of the present invention.

### BEST MODE FOR CARRYING OUT THE INVENTION

The method to achieve these goals for the patterning of resist pattern without resist pattern collapse is using novel rinse liquid in which the fluorocarbon surfactant having hydrophobic group and hydrophilic group is dissolved in deionized water. This solution is called “SPPC”, solution for preventing resist pattern collapse. It is used for the production of semiconductor devices which contain memory semiconductor device, logic device and semiconductor for the LCD products.

The fluorocarbon surfactant having both characteristics of hydrophilic group and hydrophobic group has chemical formula of CₐH_{b}F_{c}O_{d}SₑN_{f}, where “a” is an integer having range from 1 to 20, “b” is an integer having range from 0 to 30, “c” is an integer having range from 1 to 30, “d” is an integer having range from 1 to 8, “e” is an integer having range from 0 to 2, and “f” is an integer having range from 0 to 2.

The hydrophobic group is hydrocarbon or fluorocarbon and the hydrophilic group is carboxylic acid or sulfuric acid.

Here is examples for the fluorocarbon surfactant in which there are both functional group of hydrophobic group and hydrophilic group;

Difluoroacetic acid (C₂H₂F₂O₂), 2,2,3,3-Tetrafluoropropionic acid (C₃H₂F₄O₂), 3,3,3-Trifluoropropionic acid(C₃H₃F₃O₂), Heptafluorobutyric acid(C₄HF₇O₂), Tetrafluorosuccinic acid(C₄H₂F₄O₄), 3,3,3-Trifluoro-2-(trifluoromethyl) propionic acid(C₄H₂F₆O₂), 2-(Trifluoromethyl)acrylic acid(C₄H₃F₃O₂), Nonafluoropentanoic acid(C₅HF₉O₂), Hexafluoroglutaric acid(C₅H₂F₆O₄), 4,4,4-Trifluoro-3-methyl-2-butenoic acid(C₅H₅F₃O₂), 2,2,3,3,4,4,5,5,6,6,7,7-Dodecafluoroheptanoic acid(C₇H₂F₂F₁₂O₂), Trifluorobenzoic acid(C₇H₃F₃O₂), Difluorobenzoic acid(C₇H₄F₂O₂), Fluorobenzoic acid(C₇H₅FO₂), Pentadecafluorooctanoic acid(C₈HF₁₅O₂), Tetrafluoroisophthalic acid(C₈H₂F₄O₄), Tetrafluorophthalic acid(C₈H₂F₁₄O₄), Tetrafluoroterephthalic acid(C₈H₂F₄O₄), Perfluorosuberic acid(C₈H₂FI₄O₄), 2,3,4,5,6-Pentafluorophenylacetic acid(C₈H₃F₅O₂), 2,3,4,5,6-Pentafluorophenoxyacetic acid(C₈H₃F₅O₃), Perfluoroadipic acid(C6H₂F₈O₄), Pentafluorobenzoic acid(C₇HF₇), Tridecafluoroheptanoic acid(C₇HF₁₃O₂), 2,3,4,5-Tetrafluorobenzoic acid(C₇H₂F₄O₂), 2,3,4,6-Tetrafluorobenzoic acid(C₇H₂F₄O₂), Fluoro-(trifluoromethyl)benzoic acid(C₈H₄F₄O₂), 2,3,6-trifluorophenylacetic acid(C₈H₆F₂O₂), 4-(difluoromethoxy)benzoic acid(C₈H₆F₂O₃), Heptadecafluorononaic acid(C₉HF₁₇O₂), 2,3,4,5,6-Pentafluorocinnamic acid(C₉H₃F₅O₂), bis(trifluoromethyl) benzoic acid(C₉H₄F₆O₂), 2,3,4-Trifluorocinnamic acid(C₉H₅F₃O₂), Difluorocinnamic acid(C₉H₆F₂O₂), Fluorocinnamic acid(C₉H₇FO₂), (Trifluoro) acetic acid(C₉H₇F₃O₂), 4-(trifluoromethyl)manderic acid(C₉H₇F₃O₂), Nonadecafluorodecanoic acid(C₁₀HF₁₉O₂), Perfluorosebacic acid(C₁₀H₂F₁₆O₄), Bis(trifluoromethyl)phenylacetic acid(C₁₀H₆F₆O₂), 2-(trifluoromethyl)cinnamic acid(C₁₀H₇F₃O₂), 4-(3,5-difluorophenyl)4-oxobutyric acid(C₁₀H₈F₂O₃), 4-(trifluoromethyl)hydrocinnamic acid(C₁₀H₉F₃O₂), Perfluoroundecanoic acid(C₁₁HF₂₁O₂), Bis(trifluoromethyl)hydrocinnamic acid(C₁₁H₈F₆O₂), Perfluorododecanoic acid(C₁₂HF₂₃O₂), Perfluorotetradecanoic acid(C₄HF₂₇O₂), Perfluorotridecanoic acid(C₁₃HF₂₅O₂), Bis(benzoic acid) (C₁₇H₁₀F₆O₄)

One example in which the resist pattern is formed for the making semiconductor device using the SPPC, solution for preventing resist pattern collapse, is described in detail. The first step is coating wafer with photoresist and baking the wafer. The second step is exposing the photoresist with light using reticle and baking the wafer. The third step is developing the photoresist with developing solution. The fourth step is washing the photoresist with the SPPC which is the solution for preventing resist pattern collapse and dissolving fluorocarbon surfactant having hydrophobic group and hydrophilic group in deionized water. The fifth step is spin-drying the wafer and finish forming the resist pattern on the wafer. In the previous example, the fourth step can be divided into two sub steps, in which the first sub step is washing the wafer with normal deionized water for the removal of the polymer residue and developing solution. The second sub step is spraying the SPPC before spin drying. This provides advantage for low cost because the SPPC is more expensive than the deionized water and use more little SPPC for the process

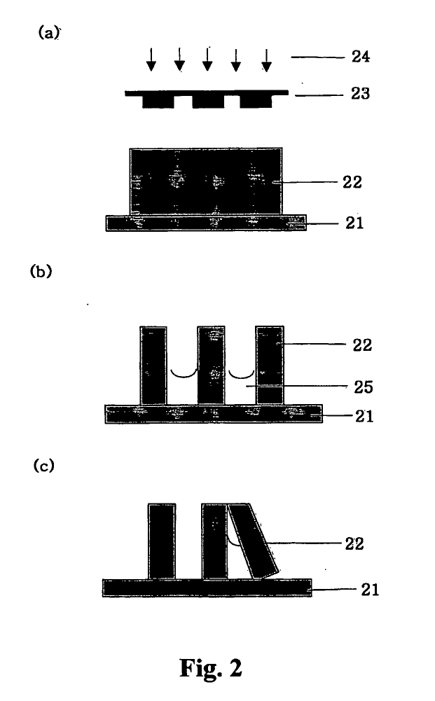

The followings are detail explanations with the attached drawing for the above example. The conventional process is explained with FIG. 2a, 2b, and 2c for comparision with this invention.

In the FIG. 2, the symbol 21 means wafer substrate, symbol 22 means photoresist, symbol 23 means mask, symbol 24 means light source and symbol 25 means developing solution.

As shown in FIG. 2a, photoresist(22) is coated on the wafer substrate(21) and then soft bake is carried out. After that light(24) is exposed through the mask(23). Post exposure bake is carried out. And resist pattern shown in FIG. 2b is formed by the treatment of developing solution. The wafer is washed with deionized water and then dried with high speed rotation of the wafer. As shown in FIG. 2c, resist pattern collapse can be brought out when the spin dry step begins after washing with deionized water.

Now the invention process is explained in detail. The invention aims for the patterning of resist pattern without resist pattern collapse using novel rinse liquid which contains the fluorocarbon surfactant having hydrophobic group and hydrophilic group in deionized water so that it have low surface tension and does not dissolve the resist pattern

The solution, which contains even small amount of the fluorocarbon surfactant having hydrophobic group and hydrophilic group in deionized water, has low surface tension and does not dissolve the resist pattern. When this solution is used for the rinse liquid, the resist pattern collapse can be prevented.

The following data demonstrate the low surface tension of the solution containing fluorocarbon surfactant having hydrophobic group and hydrophilic group in deionized water and explains the principle of lowing surface tension.

Table 1 shows the surface tension of the solution containing fluorocarbon surfactant having hydrophobic group and hydrophilic group. It was reported at the paper, Journal of Physical Chemistry, Vol. 76, No. 6,(1972) pp. 909, by Kozo Shinoda as the title of “The physicochemical properties of aqueous solutions of fluorinated surfactants”

TABLE 1
The surface tension of the solution containing fluorocarbon
surfactant having hydrophobic group and hydrophilic group.

| | Minima of | Cross |
|---|---|---|
| | Surface tention, | sectional area, |
| compound | dynes/cm | 2/molecule |
| n-C₇F₁₅SO₃Na | 37.3 | 52.5 |
| n-C₈F₁₇SO₃Li | 29.8 | 52.2 |
| n-C₈F₁₇SO₃Na | 40.5 | 52.5 |
| n-C₈F₁₇SO₃K | 34.5 | 45.1 |
| n-C₈F₁₇SO₃NH₄ | 27.8 | 41.0 |
| n-C₈F₁₇SO₃NH₃C₂H₄OH | 21.5 | 42.5 |
| n-C₈F₁₉SO₃ .1/2Mg.2H₂O | 22.0 | 45.2 |
| n-C₇F₁₅COONa | 24.6 | 42.0 |
| (CF₃)₂CF(CF₂)₄COONa | 20.2 | 43.5 |
| n-C₇F₁₅COOK | 20.6 | 43.0 |
| (CF₃)₂CF(CF₂)₄COOK | 19.5 | 47.5 |
| n-C₇F₁₅COOH | 15.2 | 41.5 |
| (CF₃)₂CF(CF₂)₄COOH | ˜15.2 | 48.0 |
| (CF₃)₂CF(CF₂)₄CH═CCHCH₂COOK* | 19.4 | — |

*In 0.02 N aqueous KOH solution

As shown in table 1, the surface tension of pentadecafluorooctanoic acid, n-C₇F₁₅COOH, is 15.2 dyne/cm. It is quite small value comparing with the fact that the surface tension of water is 72 dyne/cm, that of bromobenzene is 35.75 dyne/cm, and that of n-octanol is 27.53 dyne/cm.

The surface tension is related to the interaction between molecules so that the surface tension of water is large because it have hydrogen bond between molecules and that of surfactant is small because there is little interaction between hydrophobic groups.

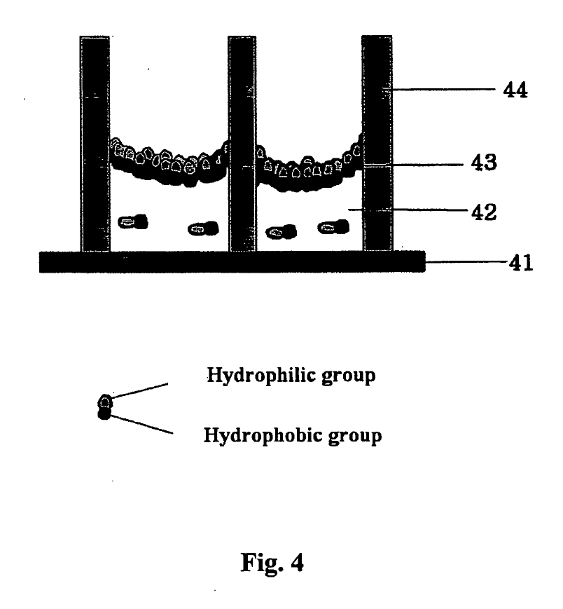

The solution containing fluorocarbon surfactant having hydrophilic group and hydrophobic group has low surface tension because the hydrophilic group of the compound in the water surface points downward to water and the hydrophobic group of the compound in the water surface points upward to air as shown in FIG. 4. The symbol 41 is wafer substrate, symbol 42 is solution for preventing resist pattern collapse, symbol 43 is fluorocarbon surfactant having both hydrophobic group and hydrophilic group, symbol 44 is photoresist.

As the number of carbon in the fluorocarbon surfactant is larger, the number of molecules whose hydrophobic group toward to air is larger and the degree of this orientation is larger, so the surface tension of the compound becomes lower.

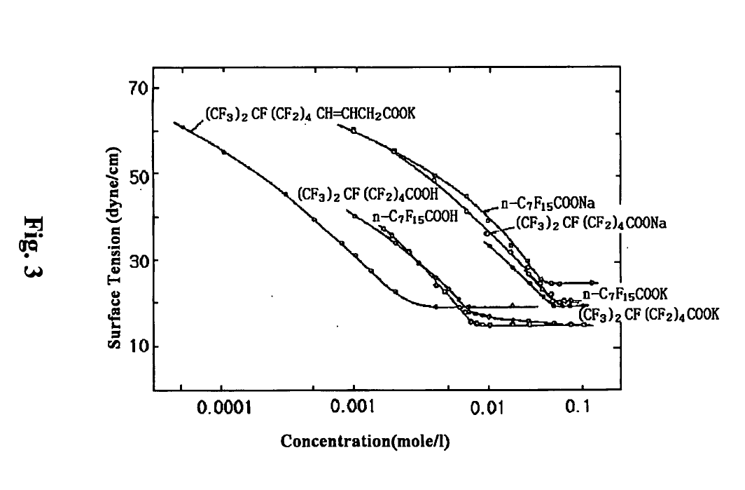

FIG. 3 shows the surface tension vs. the concentration of the fluorocarbon surfactant. This shows the small concentration of the fluorocarbon surfactant can sufficiently lower the surface tension of the solution, and this fact is important for the practical use because the fluorocarbon surfactant costs a lot.

The x axis is the concentration of the solution and the y axis is the surface tension of the solution. The solution of pentadecafluorooctanoic acid has small surface tension of 15 dyne/cm at the low concentration of 0.01M. This value is significantly low compared with normal water having surface tension of 72 dyne/cm.

According to table 1, the salt form of the fluorocarbon surfactant has also low surface tension. So the salt form of fluorocarbon surfactant with LiOH, NaOH, or KOH can be used for the making novel rinse liquid.

The salt compound of this fluorocarbon surfactant can be made with ammoniumhydroxide, Tetramethyl ammoniumhydroxide, Tetrabutyl ammoniumhydroxide, Tetrapropyl ammoniumhydroxide, ethanol ammoniumhydroxide, diethanol ammoniumhydroxide, triethanol ammoniumhydroxide.

The rinse liquid can be made by the salt compound of fluorocarbon surfactant or hydrocarbon compound having hydrophobic group and hydrophilic group with Li, Na, or NHₐR⁺_{b}OH⁻ where a is an integer ranging from 0 to 4, b is an integer ranging from 0 to 4, R is CH₃, C₄H₉, C₃H₇, C₂H₄OH, or moiety having alkyl or alcohol or ether whose number of carbon is ranging from 1 to 20.

With these properties, this solution is used for the prevention of resist pattern collapse in semiconductor device fabrication.

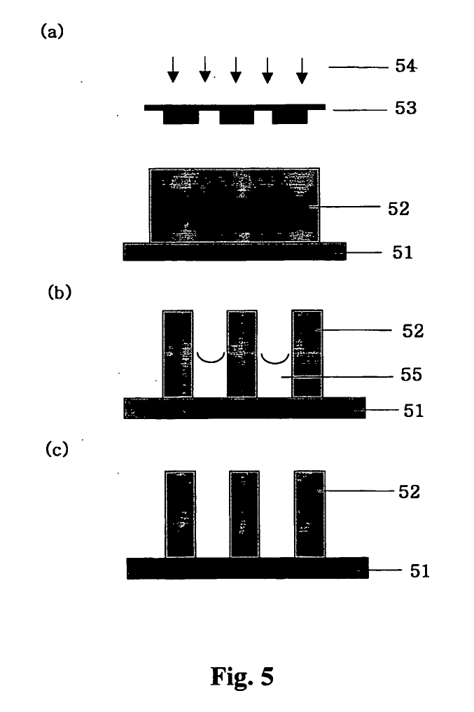

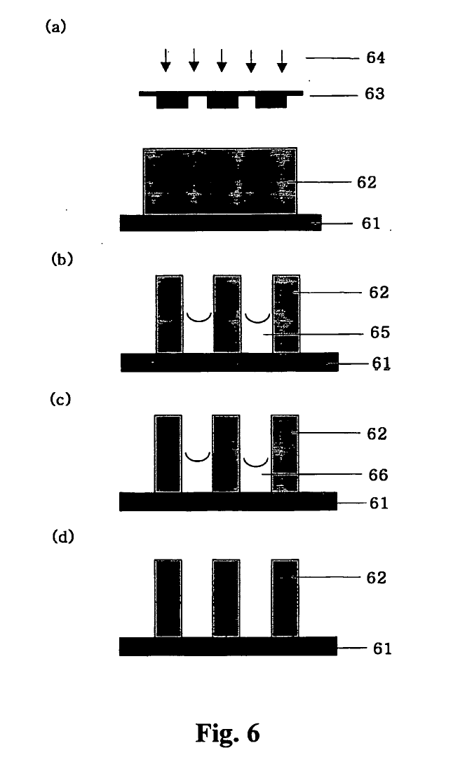

The new resist process is explained with in detail using the solution for preventing resist pattern collapse as rinse liquid with FIG. 5 and FIG. 6.

FIG. 5a, FIG. 5b, and FIG. 5c show the resist patterning method according to the example 1. The symbol 51 is wafer substrate, symbol 52 is photoresist, symbol 53 is mask, symbol 54 is light source and symbol 55 is the solution for preventing resist pattern collapse.

As shown in FIG. 5a, photoresist(52) is coated at the thickness of 4000 Å on the wafer substrate(61) and then soft bake is carried out for 90 seconds at the temperature of 100° C. After that light(54) of 248 nm wavelength is exposed through the mask(53). Post exposure bake is carried out for 90 seconds at the temperature of 100° C. Development was carried out with treatment of 2.38% TMAH developing solution, and washing with 0.02M pentadecafluorooctanoic acid solution(55) as shown in FIG. 5b. And the wafer is dried with high speed rotation of 4000 rpm. As shown in FIG. 5c, resist pattern was formed without resist pattern collapse.

The developing solution of TMAH, tetamethylammonium hydroxide, can make salt form by the reaction with acid solution of preventing resist pattern collapse, so the drain can be separated with the conventional drain of developing solution. The mixing of SPPC with developing solution can be avoided by the use of another drain for SPPC. The conventional machine for development can be easily modified to specific machine for the use of spin dry process using SPPC which have another drain, which have different drain with that of developing solution.

FIG. 6a, FIG. 6b, FIG. 6c and FIG. 6d show the resist patterning method according to the example 2. The symbol 61 is wafer substrate, symbol 62 is photoresist, symbol 63 is mask, symbol 64 is light source and symbol 65 is the deionized water, and symbol 66 is SPPC, solution for preventing resist pattern collapse.

As shown in FIG. 6a, photoresist (62) is coated at the thickness of 4000 Å on the wafer substrate(61) and then soft bake is carried out for 90 seconds at the temperature of 100° C. After that light(64) of 248 nm wavelength is exposured through the mask(63). Post exposure bake is carried out for 90 seconds at the temperature of 100° C. The development was carried out with 2.38% TMAH solution, and the washing of the wafer with deionized water(65) was carried out with the rotation of the wafer at the low speed of 500 rpm for 5 seconds as shown in drawing 6b. And then rinsing with 0.05M pentadecafluorooctanoic acid solution (66) is performed as shown in drawing 6c. After drying with high speed rotation of 4000 rpm. resist pattern was formed without resist pattern collapse as shown in drawing 6d,

The volume of used SPPC in the example 2 is smaller than that of example 1 because SPPC is used after washing with deionized water in example 2. So the example 2 is more cost effective compared with the example 1.

The solution containing fluorocarbon surfactant having hydrophobic group and hydrophilic group is used for the rinse liquid because it serves low surface tension. With this concept, the solution of hydrocarbon containing hydrophilic group and hydrophobic group can also be used for the rinse liquid if its hydrophobic group is sufficiently good so that the molecule of looking upward is high in the surface and then the solution has sufficiently low surface tension.

The chemical formula of hydrocarbon surfactant is CₐH_{b}O_{c}S_{d}NₑP_{f}, where a is integer ranging from 1 to 30, b is integer ranging from 1 to 60, c is integer ranging from 1 to 10, d is integer ranging from 0 to 2, e is integer ranging from 0 to 2, f is integer ranging from 0 to 2. The hydrophobic group is saturated hydrocarbon or unsaturated hydrocarbon, and the hydrophilic group is carboxylic acid or sulfonic acid or sulfuric acid or alcohol. The resist patterning process use novel rinse liquid in which there are one or more hydrocarbon surfactant like following; dodecyl sulfuric acid C₁₂H₂₅SO₄H, dodecyl monooxyethylene sulfuric acid C₁₂H₂₅(OCH₂CH₂)SO₄H, dodecyl dioxyethylene sulfuric acid C₁₂H₂₅(OCH₂CH₂)₂SO₄H,dodecyl trioxyethylene sulftiric acid C₁₂H₂₅(OCH₂CH₂)₃SO₄H, dodecyl hexaoxyethylene sulfuric acid, C₁₂H₂₅(OCH₂CH₂)₆SO₄H.

The invention was explained with invention example, but the range of this invention should not be limited by this example and should be interpreted with the claims of invention.

### Industrial Applicability

According to this invention, micro pattern can be formed without resist pattern collapse with usage of the solution for preventing resist pattern collapse as rinse liquid.

Additional investment for new process or new machine such as using dry development, bi-layer process or tri-layer process is not necessary because it use conventional wet development method. So it makes more cost-effective production.

1. (Deleted)

2. (Amended) A method of forming a resist pattern of a semiconductor device, comprising the steps of:
coating a photoresist onto a wafer and baking the wafer;
exposing the wafer using a mask with using 365 nm, 248 nm, 193 nm, 157 mn, EUV(13 nm), X-ray or e-beam or ion as the light source and baking the wafer;
developing the exposed photoresist with developer so that a photoresist pattern is formed;
cleaning the wafer with deionized water and evaporating a portion of the deionized water by rotating the wafer at a low speed having the range from 10 to 200 rpm;
rinsing the wafer with the deionized water to which fluorocarbon surfactant having hydrophobic group of fluorocarbon and hydrophilic group having sulfuric acid or alcohol group is added;
completing the photoresist pattern by rotating the wafer at a high speed having range from 2000 to 4000 rpm so that the deionized water to which fluorocarbon surfactant having hydrophobic group and hydrophilic group is added is evaporated.

3. (Deleted)

4. (Deleted)

5. (Deleted)

6. (Deleted)

7. (Deleted)

8. (Deleted)

9. (Amended) A method of forming a resist pattern of a semiconductor device, comprising the steps of:
coating a photoresist onto a wafer and baking the wafer;
exposing the wafer using a mask and baking the wafer;
developing the exposed photoresist with developer so that a photoresist pattern is formed;
cleaning the wafer with deionized water and evaporating a portion of the deionized water by rotating the wafer at a low speed having the range from 10 to 200 rpm;
rinsing the wafer with the deionized water to which hydrocarbon compound having hydrophobic group and hydrophilic group is added. This novel rinse liquid contains hydrocarbon surfactants having the chemical formula of CₐH_{b}O_{c}S_{d}NₑP_{f}, where a is an integer ranging from 1 to 30, b is an integer ranging from 1 to 60, c is an integer ranging from 1 to 10, d is an integer ranging from 0 to 2, e is an integer ranging from 0 to 2, f is an integer ranging from 0 to 2. If the compound is alcohol, a is an integer ranging from 5 to 30, b is an integer ranging from 1 to 60, c is an integer ranging from 1 to 10, d is an integer ranging from 0 to 2, e is an integer ranging from 0 to 2, f is an integer ranging from 0 to 2.;
completing the photoresist pattern by rotating the wafer at a high speed having the range from 2000 to 4000 rpm so that the deionized water to which hydrocarbon compound having hydrophobic group and hydrophilic group is added is evaporated.

10. (Deleted)

11. (Amended) In the claim 9, the resist patterning process use novel rinse liquid in which there is hydrocarbon surfactants having hydrophobic group and hydrophilic group. The hydrophobic group is saturated hydrocarbon or unsaturated hydrocarbon and the hydrophilic group is carboxylic acid or sulfonic acid or sulfuric acid or alcohol.

12. (Amended) In the claim 9, the resist patterning process use novel rinse liquid in which there are one or more hydrocarbon surfactant like following;
dodecyl sulfuric acid C₁₂H₂₅SO₄H, dodecyl monooxyethylene sulfuric acid C₁₂H₂₅(OCH₂CH₂)SO₄H, dodecyl dioxyethylene sulfuric acid C₁₂H₂₅(OCH₂CH₂)₂SO₄H, dodecyl trioxyethylene sulfuric acid C₁₂H₂₅(OCH₂CH₂)₃SO₄H, dodecyl hexaoxyethylene sulfuric acid, C₁₂H₂₅(OCH₂CH₂)₆SO₄H.

13. (Deleted)

14. (Deleted)

15. (Deleted)

16. (Deleted)

17. (Deleted)

18. (Amended) The rinse liquid in which the hydrocarbon compound having hydrophobic group and hydrophilic group is dissolved in deionized water. The chemical formula of the hydrocaron compound is CₐH_{b}O_{c}S_{d}NₑP_{f}, where a is an integer ranging from 1 to 30, b is an integer ranging from 1 to 60, c is an integer ranging from 1 to 10, d is an integer ranging from 0 to 2, e is an integer ranging from 0 to 2, f is an integer ranging from 0 to 2. If the compound is alcohol, a is an integer ranging from 5 to 30, b is an integer ranging from 1 to 60, c is an integer ranging from 1 to 10, d is an integer ranging from 0 to 2, e is an integer ranging from 0 to 2, f is an integer ranging from 0 to 2.
more specifically describing, the rinse liquid is made by the hydrocarbon compound whose the hydrophobic group is saturated hydrocarbon or unsaturated hydrocarbon and the hydrophilic group is carboxylic acid, sulfonic acid or sulfuric acid or alcohol
specific chemicals of the exapmle is following chemical the rinse liquid is made by the following chemical dodecyl sulfuric acid C₁₂H₂₅SO₄H, dodecyl monooxyethylene sulfuric acid C₁₂H₂₅(OCH₂CH₂)SO₄H, dodecyl dioxyethylene sulfuric acid C₁₂H₂₅(OCH₂CH₂)₂SO₄H, dodecyl trioxyethylene sulfuric acid C₁₂H₂₅(OCH₂CH₂)₃SO₄H, dodecyl hexaoxyethylene sulfuric acid, C₁₂H₂₅(OCH₂CH₂)₆SO₄H.

19. (Deleted)

20. (Deleted)

21. (Amended) In claim 18, The concentration of the hydrocarbon surfactant having hydrophobic group and hydrophilic group is ranging from 0.001M to 10M.

22. (Amended) In claim 18, The concentration of the hydrocarbon surfactant having hydrophobic group and hydrophilic group is 0.05M.

23. (Amended) The rinse liquid is made by using the salt compound of the hydrocarbon surfactant having hydrophobic group and hydrophilic group with NHₐR⁺_{b}OH⁻ where a is an integer ranging from 0 to 4, b is an integer ranging from 0 to 4, R is CH₃, C₄H₉, C₃H₇, C₂H₄OH, or moiety having alkyl or alcohol or ether whose number of carbon is ranging from 1 to 20.
More specifically describing, the rinse liquid is made by using the salt compound of hydrocarbon compound having hydrophobic group and hydrophilic group with NHₐR⁺_{b}OH⁻ which is one of following compound; ammoniumhydroxide, Tetramethyl ammoniumhydroxide, Tetrabutyl ammoniumhydroxide, Tetrapropyl ammoniumhydroxide, ethanol ammoniumhydroxide, diethanol ammoniumhydroxide, triethanol ammoniumhydroxide

24. (Deleted)

25. (Deleted)
